(19) United States
(12) Patent Application Publication
(10) Pub. No.: US 2008/0264774 A1
(43) Pub. Date: Oct. 30, 2008

(54) METHOD FOR ELECTROCHEMICALLY DEPOSITING METAL ONTO A MICROELECTRONIC WORKPIECE

(75) Inventors: Rajesh Baskaran, Kalispell, MT (US); Dakin Fulton, Kalispell, MT (US)

Correspondence Address: CHRISTENSEN, O'CONNOR, JOHNSON, KINDNESS, PLLC, 1420 FIFTH AVENUE, SUITE 2800, SEATTLE, WA, 98101-2347, US

(73) Assignee: SEMITOOL, INC., Kalispell, MT (US)

(21) Appl. No.: 11/740,117

(22) Filed: Apr. 25, 2007

(51) Int. Cl. C23C 14/00

(52) U.S. Cl. 204/192.1; 204/298.02

(57) ABSTRACT

Metal seed layers and/or barrier layers are treated to render them more suitable for subsequent electrochemical deposition of metals thereon. The processes employ thermal techniques to reduce metal oxides that have formed on the surface of the seed layers and/or barrier layers.

### FIELD OF THE INVENTION

The present invention relates to methods for electrochemically depositing metal, such as copper, onto surfaces present on a microelectronic workpiece.

### BACKGROUND

An integrated circuit is an interconnected ensemble of devices formed within a semiconductor material and within a dielectric material that overlies a surface of the semiconductor material. Devices which may be formed within the semiconductor include MOS transistors, bipolar transistors, diodes, and diffused resistors. Devices which may be formed within the dielectric include thin film resistors and capacitors. The devices utilized in each die are interconnected by conductor paths formed within the dielectric. Typically, two or more levels of conductor paths, with successive levels separated by a dielectric layer, are employed as interconnections. In current practice, copper and silicon oxide are typically used for, respectively, the conductor and the dielectric.

Despite the advantageous properties of copper, there are difficulties in depositing copper metallization and, further, due to the need for the presence of barrier layer materials. The need for barrier layer materials arises from the tendency of copper to diffuse into silicon junctions and alter the electrical characteristics of the semiconductor devices formed in the substrate. Barrier layers made of, for example, titanium nitride, tantalum nitride, etc., must be laid over the silicon junctions and any intervening layers prior to depositing a layer of copper to prevent such diffusion.

A number of processes for applying copper metallization to semiconductor workpieces have been developed. One such process is chemical vapor deposition, or CVD, in which a thin copper film is formed on the surface of a microelectronic workpiece, such as a barrier layer, by thermal decomposition and/or reaction of gas phase copper compositions. A CVD process can result in conformal copper coverage over a variety of topological profiles. Another known technique, physical vapor deposition, or PVD, can readily deposit copper on a barrier layer with relatively good adhesion compared to the adhesion achieved with CVD processes.

Electrochemical deposition of copper has been found to provide the most cost effective manner by which to deposit a copper metallization layer. In addition to being economically viable, such deposition techniques provide substantially conformal copper films that are mechanically and electrically suitable for interconnect structures. These techniques, however, are generally only suitable for applying copper to an electrically conductive layer. As such, an underlying conductive seed layer is generally applied to the workpiece surface using PVD or CVD processes before the workpiece is subjected to an electrochemical deposition process or other exposed metallic features.

It is not unusual for workpieces carrying conductive seed layers or other exposed metallic features to be stored for periods of time before they are subjected to an electrochemical deposition process to deposit copper onto them. Often, when stored for these time periods, seed layers come into contact with oxidizing conditions resulting in the formation of metal oxides on the seed layers or within the seed layers. Similar oxidation can occur to any exposed portions of other metallic features, such as underlying barrier layers. Alternatively, the seed layers and exposed portions of the barrier layers may be exposed to process conditions that promote the formation of metal oxides thereon. Such metal oxides can adversely affect the coverage of subsequently deposited metals and the adhesion between the seed layer or barrier layer and the subsequently deposited metals.

The present inventors have recognized that there exists a need to provide copper metallization processing techniques that employ barrier layers, seed layers, and electrochemical deposition processes that do not suffer from the drawbacks observed when seed layers or exposed barrier layers are exposed to oxidizing conditions prior to electrochemical deposition of metals thereon.

### SUMMARY

Processes described herein provide methods for electrochemically depositing metals onto a microelectronic workpiece with satisfactory conformal deposition of metal films and void-free filling of high aspect ratio features that have been exposed to oxidizing condition prior to an electrochemical deposition process. The processes described herein achieve this result, in part, by treating formed seed layer and/or exposed portions of barrier layer materials to increase their suitability as a substrate upon which additional metals are electrochemically deposited. The methods described herein achieve this result without requiring additional complicated process steps or expensive process equipment.

The processes described herein are applicable to a wide range of processes used in the manufacture of a metallization layer on a workpiece, such as a microelectronic workpiece. The workpiece may, for example, be a semiconductor workpiece that is processed to form integrated circuits or other microelectronic components. Without limitation as to the applicability of the disclosed subject matter, a process for depositing copper is described.

A process for forming a metal feature on a microelectronic workpiece having a barrier layer deposited on a surface thereof includes the step of forming a metal seed layer on the barrier layer. This seed layer can have a thickness that varies and may be formed from materials that can serve as a seed layer for subsequent metal electrochemical deposition. Such metals include, for example, copper, copper alloys, aluminum, aluminum alloys, nickel, and nickel alloys. In accordance with the present disclosure, the seed layer and exposed portions of the barrier layer are thermally treated in an environment at an elevated temperature in order to render the seed layer and/or exposed barrier layer or both more suitable for a subsequent electrochemical deposition of metal thereon. The subsequent electrochemical metal deposition thereon can be an enhancement of the existing metal seed layer achieved by depositing additional metal thereon in a separate deposition step, or it can be gap fill metallization.

### DESCRIPTION OF THE DRAWINGS

The foregoing aspects and many of the attendant advantages of the subject matter described herein will become more readily appreciated as the same become better understood by reference to the following detailed description, when taken in conjunction with the accompanying drawings, wherein:

FIGS. 1A-1D are cross-sectional views through a semiconductor workpiece illustrating the various layers of material as they are applied in accordance with one embodiment of the process described herein;

FIGS. 2A-2C are cross-sectional views of trenches filled with metal without treatment in accordance with processes described herein;

FIGS. 3A-3C are cross-sectional views of trenches filled with metal after being treated in accordance with processes described herein;

FIGS. 4A-4C are cross-sectional views of trenches filled with metal without treatment in accordance with processes described herein;

FIGS. 5A-5C are cross-sectional views of trenches filled with metal after being treated in accordance with processes described herein; and

FIG. 6 is a schematic illustration of a tool for carrying out processes described herein.

### DETAILED DESCRIPTION

Although the embodiments of the processes disclosed herein are described in connection with copper metallization, it is understood that the basic principles of the processes described herein can be applied to other metals or alloys that are capable of being electrochemically deposited. Such metals include iron, nickel, cobalt, zinc, copper-zinc, nickel-iron, cobalt-iron, platinum, gold, tin, lead-tin alloys, silver, silver-tin, silver-tin, copper-alloys, and lead.

Described below is an approach to applying copper metallization to a workpiece, such as a semiconductor workpiece. In accordance with the disclosed process, an electrolytic copper bath is used to electroplate copper onto a seed layer, electroplate copper directly onto a barrier layer material, or enhance an ultra-thin copper seed layer which has been deposited on the barrier layer using a deposition process such as PVD. Additionally, a method for applying a metallization layer will be disclosed.

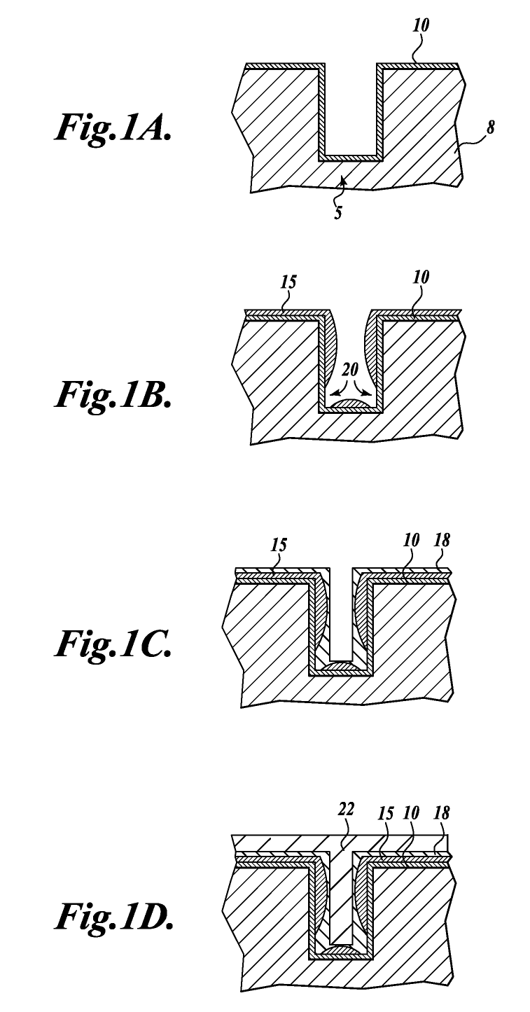

A cross-sectional view of a micro-structure, such as trench 5, that is to be filled with copper is illustrated in FIG. 1A and will be used to describe seed layer enhancement using processes described herein. As shown, a thin barrier layer 10 of, for example, titanium nitride or tantalum nitride is deposited over the surface of a semiconductor device or, as illustrated in FIG. 1A, over a layer of a dielectric 8, such as silicon dioxide. The barrier layer 10 acts to prevent the migration of copper to any semiconductor device formed in the substrate. Any of the various known techniques, such as CVD or PVD, can be used to deposit the barrier layer depending on the particular barrier material being used. While the following description proceeds in the context of the seed layer enhancement, it should be understood that the processes described herein can also be applied to a seed layer that is not to be subjected to a subsequent seed layer enhancement step.

Referring to FIG. 1B, after the deposition of the barrier layer, an ultra-thin copper seed layer 15 is deposited on the barrier layer 10. The resulting structure is illustrated in FIG. 1B. Preferably, the copper seed layer 15 is formed using a vapor deposition technique, such as CVD or PVD. Copper seed layer 15 may be relatively thick, e.g., 1000 Angstroms, or it may be thinner, for example, about 50 to about 500 Angstroms. The thicker seed layers generally exhibit adhesion and copper coverage that is greater than the adhesion and copper coverage resulting when a thinner layer of copper seed layer is employed. On the other hand, thinner copper seed layers can be more desirable in certain instances because they have less tendency to pinch off the trenches to be filled, as compared to the thicker seed layers. In addition, thinner copper seed layers may be desirable for repair purposes from the standpoint of minimizing the thieving at Cu surfaces due to a smaller difference in resistance between thinner Cu and the exposed barrier layer.

It has been observed that the seed layer 15 may not coat the barrier layer 10 in a uniform manner, particularly when it is of the thinner variety. Rather, voids or non-continuous seed layer regions on the sidewalls of the trench, such as at 20, can be present in a seed layer 15, thereby affecting the subsequent electrochemical deposition of a copper layer in the regions 20. As such, seed layer 15 may not be fully suitable for traditional electroplating techniques typically used after application of a seed layer.

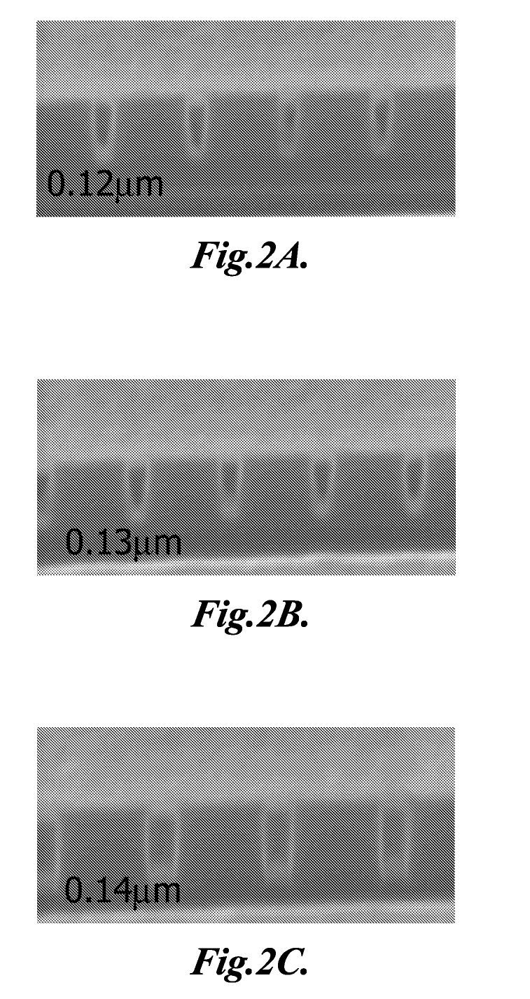

The suitability of the seed layer for subsequent electrochemical deposition of metals can be improved if it is subjected to a subsequent electrochemical seed layer enhancement technique. To this end, the semiconductor workpiece is subjected to a subsequent process step in which a further amount of copper 18 is applied to the original seed layer 15 to thereby enhance the seed layer. A seed layer enhanced by the additional deposition of copper 18 is illustrated in FIG. 1C. As shown in FIG. 1C, the void or non-continuous regions 20 of FIG. 2B have been filled, thereby leaving substantially all of the barrier layer 10 covered with copper. Such seed layer enhancement process is described in U.S. Pat. No. 6,290,833, the subject matter of which is incorporated herein by reference.

After the seed layer has been deposited and before or after a seed layer enhancement, it is not unusual for the microelectronic workpieces to be stored for periods of time during which the workpieces are exposed to conditions that result in the oxidation of the seed layer metals or any exposed portions of the barrier layer metal. Alternatively, the microelectronic workpiece may be subjected to processes that expose the seed layer and exposed portions of the barrier layer to conditions that result in the oxidation of one or both. The presence of oxides on the seed layer and/or the exposed portions of the barrier layer can adversely affect metal that is deposited thereon using electrochemical deposition techniques. For example, copper electrochemically deposited onto seed layers that include metal oxides at the seed layer surface suffer from a reduction in adhesion properties between the seed layer and the electrochemically deposited copper. The processes described herein treat the seed layers and exposed portions of the barrier layer to render them more suitable for the subsequent electrochemical deposition of metals thereon. In one embodiment, the processes described herein thermally treat those features in an environment at an elevated temperature.

In accordance with this embodiment, after the seed layer has been formed, whether it be a seed layer of conventional thickness or thinner seed layer, and before subsequent electrochemical deposition of additional metal, the microelectronic workpiece is thermally treated in an environment that promotes the reduction of oxides back to metal or other species that are more suitable for receiving a subsequently deposited metal. This result can be achieved by employing an environment temperature and a time period that provides the necessary energy requirements to reduce the metal oxide to metal or other desirable species.

The energy needed to achieve the desired reduction of metal oxides to metal can be represented by an Arrhenius-type of relationship. The Arrhenius relationship is reflected by the formula:

$$E = {E}_{0} exp ( - \frac{{Q}_{act}}{RT} )$$

For copper oxide, the reduction of copper oxide to copper requires an activation energy Of Q_{act}˜257 KJ/mol. E₁ is the total energy requirement, E₀ is the pre-exponent constant, R is the universal gas constant, and T₁ is the temperature in Kelvin.

Assuming the reduction of copper oxide follows an Arrhenius-type relationship:

$${E}_{1} = {E}_{0} exp ( - \frac{Q}{{RT}_{1}} ) {E}_{2} = {E}_{0} exp ( - \frac{Q}{{RT}_{2}} )$$

where T₁ is a first temperature and T₂ is a second temperature, E₁ and E₂ represent the total energy requirement at T₁ and T₂, respectively. The total energy for reduction equals the total energy requirement E_{X} multiplied by the length of time t_{X} at T_{X}. In other words:
E₁t₁=E₂t₂ =Total energy for reduction
Where t₁, t₂ are the times at different temperatures T₁ and T₂.
From the above relationships:

$${t}_{1} exp ( - \frac{Q}{{RT}_{1}} ) = {t}_{2} exp ( - \frac{Q}{{RT}_{2}} )$$

and the ratio of t₁ and t₂ is given by:

$$\frac{{t}_{1}}{{t}_{2}} = exp [ \frac{Q}{R} ( \frac{1}{{T}_{1}} - \frac{1}{{T}_{2}} ) ]$$

From this relationship, given a t₁ and a T₁ that provide the desired reduction of copper oxide, a different time (t₂) and for a different temperature (T₂) can be calculated to achieve the desired reduction of copper oxide. Similar relationships can be determined between time and temperature for metals exhibiting other activation energies.

Suitable temperatures fall within the range of about 100° C. to about 400° C. The temperature are chosen so that the seed layer oxide and oxide on the exposed portion of the barrier layer are reduced without damaging the copper and barrier metal. If the temperature is too high, the seed layer metal will tend to agglomerate into groups instead of remaining evenly distributed on the barrier layer surface. If the temperature is too low, no reduction of the oxides will be affected.

The atmosphere within the environment in which the thermal treatment is carried out should be essentially free of components that would otherwise promote the oxidation of the seed layer or exposed portions of the barrier layer. Examples of environments that are suitable include those containing hydrogen, argon, nitrogen, boron, ammonia, or boro-hydride based gases, or mixtures thereof. Preferably, the environment is composed of hydrogen, argon, nitrogen, or boron gases, or mixtures thereof.

The thermal treatment can be carried out at atmospheric pressure, above atmospheric pressure, or below atmospheric pressure. The particular pressure employed may be affected by the means used to provide the non-oxidizing atmosphere within the thermal treatment chamber. For example, if the non-oxidizing atmosphere is to be introduced by purging the vessel in which the thermal treatment is to be carried out, the pressure in the vessel may be above atmospheric. On the other hand, if the non-oxidizing atmosphere is to be provided by evacuating the vessel and then introducing a non-oxidizing gas, the pressure within the environment may be below atmospheric.

In accordance with the discussion above, the thermal treatment should be carried out for a length of time needed to achieve a desired reduction of the oxides given the temperature of the environment where the thermal treatment occurs. Exemplary time periods range in length from about 30 seconds to 4 minutes.

Referring to FIGS. 2A-2C, cross sections of trenches that have been treated to electrochemically deposit copper into trenches 0.12, 0.13, and 0.14 micrometers wide are illustrated. Prior to the electrochemical deposition of copper, a barrier layer of tantalum nitride/tantalum about 20-30 nanometers thick was formed, followed by PVD deposition of copper seed layer having a thickness of about 20 nanometers. Voids within the deposited features are evident by the darker portions within the trenches.

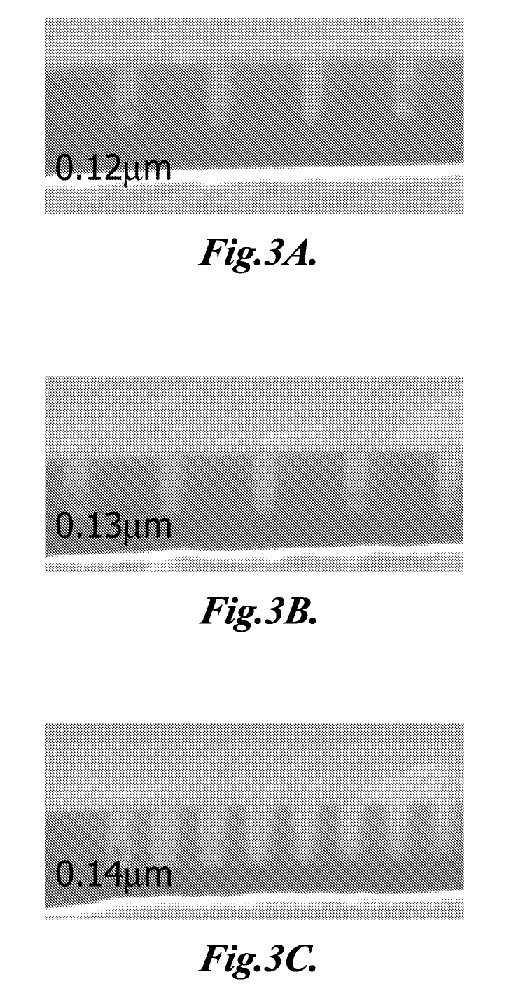

Referring to FIGS. 3A-3C, the 20 nanometer PVD seed layer and 20-30 nanometer PVD barrier layer were thermally treated at about 200° C in a gaseous environment of argon-hydrogen (98% argon, 2% hydrogen) gas for about one minute before copper was electrochemically deposited thereon. Comparing FIGS. 2A-2C and FIGS. 3A-3C, reduced void formation is evident for the 0.12, 0.13, and 0.14 micrometer trenches of FIGS. 3A-3C that were thermally treated.

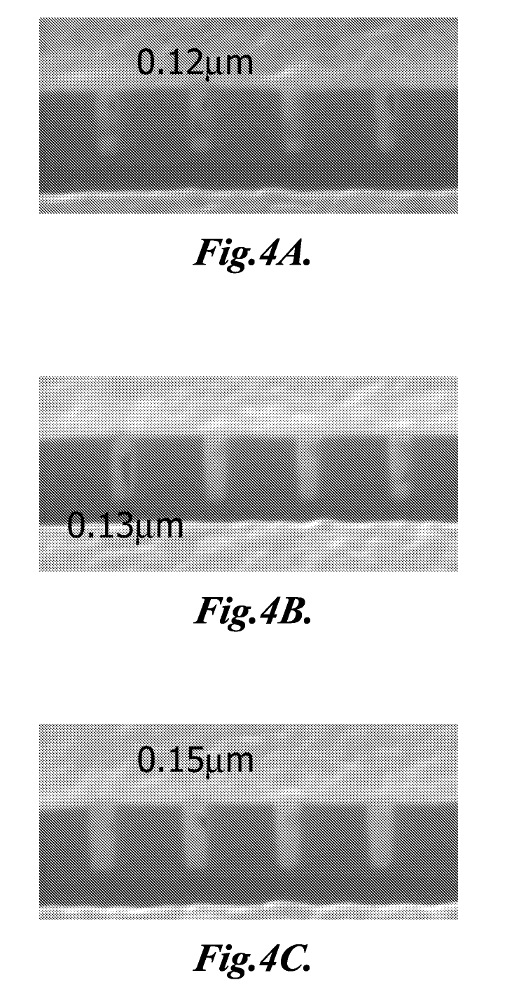

Referring to FIGS. 4A-4C, the results of electrochemical deposition of copper within trenches 0.12, 0.13, 0.14 and 0.15 micrometers wide are illustrated. The trenches include a PVD barrier layer of tantalum nitride/tantalum having a thickness of about 20-30 nanometers and a PVD copper seed layer having a thickness of about 50 nanometers. In FIGS. 4A-4C, voids in the electrochemically deposited copper are indicated by the darker portions within the trenches.

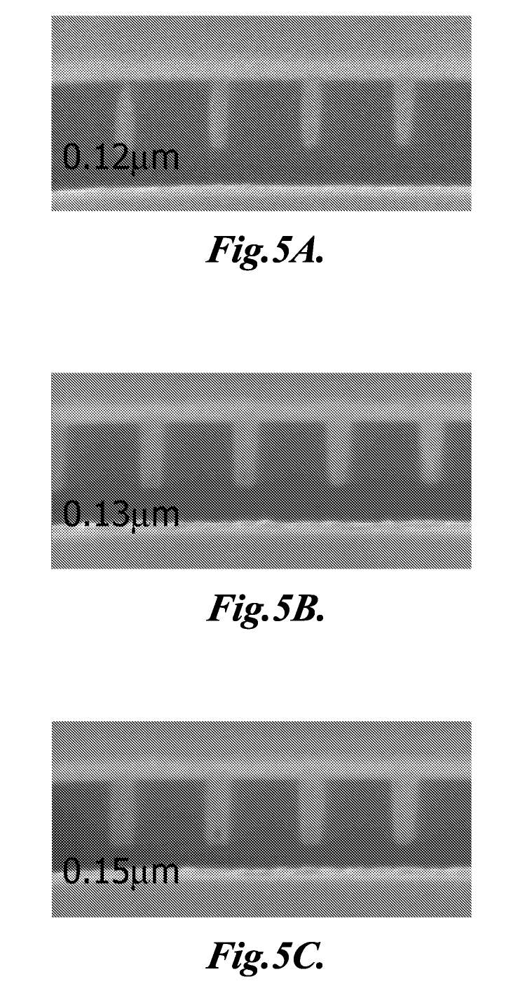

Referring to FIGS. 5A-5C, prior to the electrochemical deposition of copper within the trenches, the barrier layer and seed layer were thermally treated at 200° C. in a argon-hydrogen (98% argon, 2% hydrogen) atmosphere for about one minute before copper was electrochemically deposited thereon. In FIGS. 5A-5C, fewer voids are observed compared to the features within the trenches in FIGS. 4A-4D.

From the foregoing, the benefits of the thermal treatment process described herein are evidenced by a reduced formation of voids within copper features that are electrochemically deposited onto seed layers/barrier layers treated in accordance with the processes described herein.

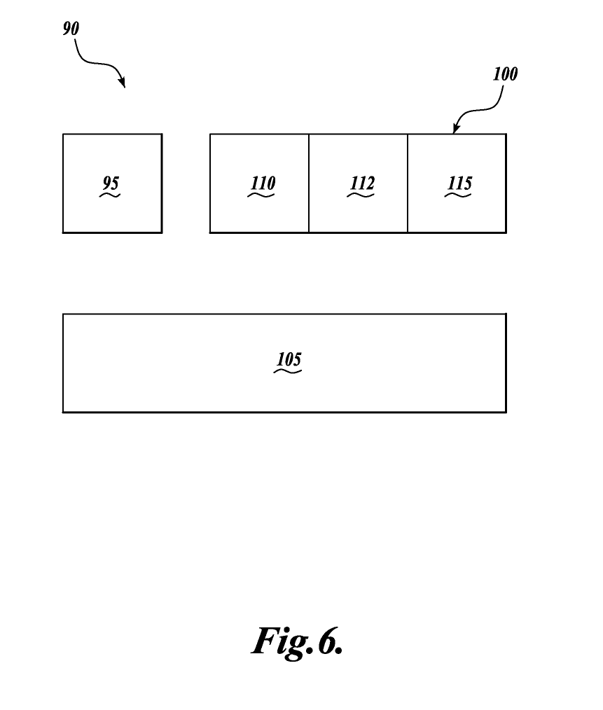

Referring to FIG. 6, a schematic representation of a section of a semiconductor manufacturing line 90 suitable for implementing the processes described herein is illustrated. Line 90 includes a vapor deposition tool or tool set 95 and an electrochemical copper deposition tool or tool set 100. Transfer of wafers between the tools/tool sets 95 and 100 may be implemented manually or through an automated transfer mechanism 105. Preferably, automated transfer mechanism 105 transfers workpieces in a pod or similar environment. Alternatively, the transfer mechanism 105 may transfer wafers individually or in an open carrier through a clean atmosphere joining the tools/tool sets.

In operation, vapor deposition tool/tool set 95 is utilized to apply a barrier layer and a copper seed layer over at least portions of semiconductor workpieces that are processed on line 90. Preferably, this is done using a CVD or PVD application process. After application of the copper seed layer, the semiconductor workpieces are further treated within tool/tool set 95 to thermally treat them in an elevated temperature environment under an atmosphere that promotes the reduction of metal oxides to metals. The thermally treated workpieces are then transferred to tool/tool set 100, either individually or in batches, where they are subject to electrochemical seed layer enhancement or gap fill metal deposition at, for example, processing station 110. After seed layer enhancement or gap metallization is completed, the workpieces are subject to cleaning, such as deionized water rinse at station 112, before being transferred to station 115 for further processing, such as thermal annealing. The electrochemical deposition tool set 100 may be implemented using, for example, an LT-210™ model, Raider™ or an Equinox™ model plating tool available from Semitool, Inc., of Kalispell, Mont.

While illustrative embodiments have been illustrated and described, it will be appreciated that various changes can be made therein without departing from the spirit and scope of the invention.

1. A method for electrochemically depositing a metal onto a microelectronic workpiece comprising the steps:
depositing a seed layer on a surface of the microelectronic workpiece;
thermally treating the microelectronic workpiece and thereby reducing seed layer metal oxide to metal;
treating the thermally treated microelectronic workpiece to provide an enhanced seed layer wherein non-continuous regions of the seed layer are filled; and
electrochemically depositing metal onto the enhanced seed layer.

2. The method of claim 1, wherein the step of depositing a seed layer is carried out using a first deposition process and the electrochemically depositing step is carried out using a second deposition process.

3. The method of claim 1, wherein the thermally treating step is carried out in the presence of reducing gas.

4. The method of claim 3, wherein the reducing gas is selected from hydrogen, argon, nitrogen, boron, ammonia, boro-hydride based gas, or mixtures thereof.

5. The method of claim 4, wherein the reducing gas is selected from hydrogen, argon, nitrogen, boron gas, or mixtures thereof.

6. The method of claim 5, wherein the thermally treating step is carried out in an environment at a temperature ranging from about 100° C. to 400° C.

7. The method of claim 1, wherein the thermally treating step is carried out in an elevated pressure environment.

8. The method of claim 1, wherein the thermally treating step is carried out in a reduced pressure environment.

9. The method of claim 1, wherein the thermally treating step is carried out in an atmospheric pressure environment.

10. The method of claim 1, wherein the thermally treating step is carried out for a time period ranging in length from about 30 seconds to 4 minutes.

11. A tool for electrochemically depositing metal onto a microelectronic workpiece comprising:
a station for depositing a seed layer onto a surface of the microelectronic workpiece;
a station for exposing the workpiece to an elevated temperature in an atmosphere that promotes the reduction of metal oxides of the seed layer to metal;
a station for treating the workpiece after the metal oxides of the seed layer are reduced to metal to provide an enhanced seed layer wherein non-continuous regions of the seed layer are filled; and
a station for electrochemically depositing metal onto the enhanced seed layer.

12. A method for electrochemically depositing a metal onto a microelectronic workpiece comprising the steps:
depositing a barrier layer on a surface of the microelectronic workpiece;
depositing a seed layer onto the barrier layer;
thermally treating the microelectronic workpiece and thereby reducing seed layer metal oxide to metal and barrier layer metal oxide to metal; and
electrochemically depositing metal onto the thermally treated seed layer and barrier layer.

13. The method of claim 12, wherein the step of depositing a seed layer is carried out using a first deposition process and the electrochemically depositing step is carried out using a second deposition process.

14. The method of claim 12, wherein the thermally treating step is carried out in the presence of reducing gas.

15. The method of claim 14, wherein the reducing gas is selected from hydrogen, argon, nitrogen, boron, ammonia, boro-hydride based gas, or mixtures thereof.

16. The method of claim 15, wherein the thermally treating step is carried out in an environment at a temperature ranging from about 100° C. to 400° C.

17. The method of claim 12, wherein the thermally treating step is carried out for a time period ranging in length from about 30 seconds to 4 minutes.

18. A tool for electrochemically depositing metal onto a microelectronic workpiece comprising;
a station for depositing a barrier layer on a surface of the microelectronic workpiece;
a station for depositing a seed layer onto the barrier layer;
a station for exposing the workpiece to an elevated temperature in an atmosphere that promotes the reduction of metal oxides of the seed layer to metal and metal oxides of the barrier layer to metal; and
a station for electrochemically depositing metal onto the thermally treated seed layer and barrier layer.
